(19) United States
(12) Patent Application Publication
(10) Pub. No.: US 2015/0323864 A1
(43) Pub. Date: Nov. 12, 2015

(54) Lithographic patterning of insulating or semiconducting solid state material in crystalline form

(71) Applicant: The Regents of the University of California, Oakland, CA (US)

(72) Inventors: Simon Karl Moser, Lausanne (CH); Luca Moreschini, Berkeley, CA (US); Eli Rotenberg, Oakland, CA (US)

(21) Appl. No.: 14/713,154

(22) Filed: May 15, 2015

Related U.S. Application Data
(63) Continuation of application No. PCT/IB2013/060328, filed on Nov. 22, 2013.
(60) Provisional application No. 61/729,366, filed on Nov. 22, 2012.

(51) Int. Cl. G03F 7/004; G03F 7/20

(52) U.S. Cl. CPC G03F 7/0043; G03F 7/20

(57) ABSTRACT

A method for lithographic patterning of an insulating or semiconducting solid state material in crystalline form, said method comprising a step where said material is exposed to an amount of radiation which is sufficient to change its insulating or semiconducting state into a conducting state.

### RELATED APPLICATIONS

This application is a continuation of International Application No. PCT/IB2013/060328, filed 22 Nov. 2013, which claims priority to U.S. Provisional Patent Application Ser. No. 61/729,366, filed 22 Nov. 2012.

### STATEMENT OF GOVERNMENT SUPPORT

This invention was made with government support under Contract No. DE-AC02-05CH11231 awarded by the U.S. Department of Energy. The government has certain rights in this invention.

### FIELD OF INVENTION

The present invention relates to lithographic patterning of insulating or semiconducting solid state material in crystalline form that changes its electronic state under ionizing radiation.

### BACKGROUND OF THE INVENTION

In material sciences, there is an ongoing quest for new materials with properties suitable to revolutionize current technological standards. Silicon which was on the base of 50 years of electronic development, is reaching its limits. Neither can silicon based devices be further down-scaled, nor can their efficiency be raised. This accounts e.g. for aspects like chip size and energy consumption in chip technology, or energy harvesting efficiency in photovoltaic applications. Besides, fabrication of silicon based devices is energy intense with associated ecological problems. In order to overcome some of the drawbacks of silicon, major current interest focuses on oxides as potential material systems. Some of those are believed to allow for new types of electronics as well as for efficient light-harvesting devices. Beyond their non-toxicity and low corrosiveness, they are typically low in price.

In some cases like TiO₂, oxides have indeed shown to allow for new applications. An interface of stoichiometric TiO₂ with oxygen reduced TiO₂₋ₓ can be used as active channel in a new electronic component called a memristor . However, device fabrication still faces irreproducibility due to a lack of control of the stoichiometry in the switching unit.

Beyond, the electronic band structure of some oxides like TiO₂ or ZnO is highly favorable for photo-catalytic as well as photovoltaic applications¹⁻⁸. Either in bulk or nano-crystalline form, the band gap is well aligned to the red-ox-potentials of water and carbon dioxide, and therefore its applicability as a large scale photo-catalyst for water splitting or greenhouse gas reduction is promising. On top of that, the absorption spectra of these oxides typically covers the whole UV light region, and progress to extend absorption further to the VIS and NIR region (e.g. in case of TiO₂ by Cr—N-co-doping) is currently made⁹⁻¹¹.

However, a major drawback of state of the art oxide based solar cells and catalysts, is its low charge transport efficiency. The recombination time of electrons and holes is still much shorter than the time the charge carriers need to reach an electrode, and if they do, recombination can still take place at the interface. Hence, there is a high demand for non-recombining charge transport channels in order to increase the quantum yield of oxide based devices.

The technology presented in this invention allows to directly writing long living charge transport channels into intrinsically insulating oxides by use of standard lithography, without disturbing the crystalline quality of the sample. In this highly controlled fashion, the oxide structure may be used as photoactive material and transport channel at the same time, reducing the number of heterogeneous interfaces and such the number of possible charge recombination centers. Consequently, this patterning technique in principle allows collecting charge closer to the creation center than the typical electron hole recombination length scale. Additionally, it should help to avoid further steps in the productive chain, since further materials in principle are not needed to play the role of an electrode. We demonstrate the technology presented in this patent application explicitly for TiO₂ anatase based compounds. The method in principle does not need the development of new infrastructure but can base on standard UV, EUV and e-beam lithography techniques.

### SUMMARY OF THE INVENTION

The goal of the invention is to allow for direct lithographic patterning of insulating or semiconducting solid state material in crystalline form that changes its electronic state from insulating to conducting under ionizing radiation. High energy radiation like x-rays, electrons and alike can in principle create anion vacancies in these compounds resulting in an effective change of the mobile charge carrier concentration and hence to a net change of the electronic state of the material.

The invention therefore relates to a method for lithographic patterning of an insulating or semiconducting solid state material in crystalline form, said method comprising a step where said material is exposed to an amount of radiation which is sufficient to change its insulating or semiconducting state into a conducting state.

Preferably the radiation energy is between 80 and 100 eV.

One embodiment of the invention applies directly to a lithographic patterning method of TiO₂ anatase based electronic devices such as solar cells, photo catalysis applications, memristors r the like. The anatase based samples in principle can be on hand in a mono-crystalline, poly-crystalline and/or nano-crystalline form (e.g. (branched) nano-rods, nano-particles, . . . ). The method comprises UV-, EUV-, electron beam- and all other lithographic techniques involving ionizing radiation to spatially modify the electronic state (e.g. dielectric constant, conductivity, etc.) of the material, in this explicit case anatase.

First, the invention allows tuning the electronic state of anatase continuously from an insulator to a metal, without destroying its crystalline quality. Hence, efficiency losses at heterogeneous metal-semiconductor junctions and interfaces, as well as impurity recombination can be avoided. Second, the invention in principle enables low cost large scale fabrication of devices on industrial standard wafers, using state of the art lithography methods. As a third advantage, additional materials for electrodes can be avoided and additional steps in device fabrication can be spared. This can help cutting production costs and help reduce waste handling problems which e.g. can make anatase based solar energy harvesting devices more competitive. The current general interest of the material science community as well as industry in oxide technology is a promising argument that this invention could have a significant impact in the future.

### BRIEF DESCRIPTION OF THE FIGURES

FIG. 1A shows the CE map (T=20 K, hv=85 eV) of oxygen-vacant anatase (001) with nₑ=2×10²⁰ cm⁻¹. Dashed lines indicate projections of the 3D Brillouin zone. Electron pockets are seen at (0; 2π/a) and (−2π/a; 4π/a), which correspond to Γ-points at this photon energy. Black arrows indicate ARPES signatures of the (4×1) surface reconstruction.

FIG. 1B shows the kₓk_{z} CE map at E=E_{F} extracted from a photon energy scan for k_{y}=2π/a (dashed line in FIG. 1A).

FIG. 1C shows the CB dispersion at k_{y}=2π/a (dashed line in FIG. 1A) for a sample with nₑ=3.5×10¹⁹ cm (T=20 K, hv=85 eV).

FIG. 2A shows the results of a time and temperature dependent study of the oxygen vacancy formation in anatase during 85 eV X-rays irradiation. After about 100 s the metallic state saturates while oxygen vacancy formation continues. The effect does not depend on temperature.

FIG. 2B shows the results of the reverse process of the process shown in FIG. 2A. After about 100 s metallic state and oxygen vacancy signal only diminish slightly due to oxygen vacancies diffusing into the bulk.

FIG. 2C shows the control of the charge carrier concentration by oxygen vacancy doping. Regulating the oxygen partial pressure and photon flux at the same time allows to fine tune the number of charge carriers from 10¹⁷ to 10²⁰ cm⁻³. The stack of momentum distribution curves shows the consequent change of the Fermi wave vector k_{F}.

FIG. 3A and FIG. 3B show that in a first step, the x-ray beam is guided along a stoichiometric anatase thin film following the pattern shown in these figures.

FIG. 3C and FIG. 3D show that after the first step, the same region is probed by imaging the photoemission intensity at the Fermi level. Since the probing step involves x-rays which oxygen vacancy dope the sample, the background intensity is never completely zero. The vertical streaks result from the electron beam induced by RHEED measurement during growth.

FIG. 4A shows a typical EUV lithography system containing UV light source, condensing optics, mask and focusing mirrors.

FIG. 4B shows a typical electron beam lithography setup containing electron source, electromagnetic lenses and detectors.

### DETAILED DESCRIPTION OF THE INVENTION

### Applicable Material Systems

Beyond TiO₂ anatase, the method described here applies to any insulating or semiconducting solid state material in crystalline form that changes its electronic state under ionizing radiation. Radiation like x-rays, electrons and alike can create anion vacancies in these compounds which potentially lead to an effective doping and hence to a change of its electronic properties.

In general, this includes all oxides, sulfides, selenides, tellurides, nitrides, phosphides, arsenides, fluorides, chlorides, bromides, carbides or iodides of the transition and rare earth metals (including lanthanide and actinide series), with the alkali metals or alkaline earth metals often being present in the compounds.

Further, alloys of like compounds with each other, which can have a wide range of composition if they are mutually soluble in each other. Then there are the mixed compounds, in which there are two, three or more different metal atoms combined with some number of the electronegative elements.

The following items are also included, the list is not exhaustive:
All carbonates of silicon (in particular SiCO₄), as well as their various other ternary and higher order compounds.
All oxides, especially of, Al, Ga, In, Sn, Tl, Pb, Bi, Po B, Si, Ge (e.g. PbO₂, SiO₂, SnO₂).
The oxides of the alkali metals and the alkaline earth metals (e.g. Na₂O, MgO, CaO).
The oxides of the rare earth metals (including lanthanide and actinide series).
The various oxides of a transition metal (group 3 to 12 of the periodic table including oxides of Sc, Ti, V, Cr, Mn, Fe, Co, Ni, Cu, Zn Y, Zr, Nb, Mo, Tc, Ru, Rh, Pd, Ag, Cd, Hf, Ta, W, Re, Os, Ir, Pt, Au, Hg, Rf, Db, Sg, Bh, Hs, Mt, Ds, Rg, Cn, as well as their various other ternary and higher order compounds. (e.g. ZnO, WO₃, MnO₂, Mn₂O₃, Mn₃O₄, MnO, MnOₓ, MnO₂₋ₓ, NiO, PtO1₂, IrO₂, RuO₂, Co₃O₄, Fe₃O₄, TiO₂, TiOₓ, TiO₂₋ₓ, MoO₃).
The semiconducting nitrites, explicitly the nitrites of aluminum (including AlN), of silicon, of gallium, of titanium (including TiN), of tantalum, of hafnium (including HfN), of germanium, and of lanthanum.
The various nitrites of a transition metal (group 3 to 12 of the periodic table including oxides of Sc, Ti, V, Cr, Mn, Fe, Co, Ni, Cu, Zn Y, Zr, Nb, Mo, Tc, Ru, Rh, Pd, Ag, Cd, Hf, Ta, W, Re, Os, Ir, Pt, Au, Hg, Rf, Db, Sg, Bh, Hs, Mt, Ds, Rg, Cn, as well as their various other ternary and higher order compounds as well as the rare earth nitrites (including lanthanide and actinide series), and alloys of these compounds and more complex mixed metal nitrites.
Sulfides and selenides of the transition metals with some ionic bonding character, essentially the S and Se analogues of the oxides mentioned above, especially all sulfides of molybdenum (including MoS₂), sulfides of Cadmium (including CdS), sulfides of tungsten (including WS₂), sulfides of ruthenium (including RuS₂), sulfides of zirconium (including ZrS₂), selenides of Cadmium (including CdSe), selenides of tungsten (including WSe₂), selenides of molybdenum (including MoSe₂), tellurides of molybdenum (including MoTe₂)
Phosphides and arsenides of various transition and rare earth metals, e.g., Sc, Y, La, etc., especially all phosphides of Gallium (including GaP), arsenides of Gallium (including GaAs).
Semiconducting halides, such as CuCl, CuBr, and AgCl.

Examples for higher order and other complex oxides:
a) titanates (Sr₂TiO₄, Sr₃TiO₇, Ba₂TiO₄, Ba₃TiO₇)
b) iridates (Ba₂IrO₄, Ba₃IrO₇, Sr₂IrO₄, Sr₃IrO₇)
c) cuprates ((Tl₅Pb₂)Ba₂Mg₂Cu₉O ₁₇+, (Tl₅Pb₂)Ba₂MgCu₁₀O₁₇+, (Tl₄Pb)Ba₂MgCu₈O ₁₃+, (Tl₄Ba)Ba₂MgCu₈O ₁₃+, (Tl₄Ba)Ba₂Mg ₂Cu₇O₁₃+, (Tl₄Ba)Ba₂Ca₂Cu₇O₁₃+, (Tl₄Ba)Ba₄Ca₂Cu₁₀O_{y}, Tl₅Ba₄Ca₂Cu₁₀O_{y}, (Sn₅In)Ba₄Ca₂Cu₁₁O_{y}, (Sn₅In)Ba₄Ca₂Cu₁₀O_{y}, Sn₆Ba₄Ca₂Cu₁₀O_{y}, (Sn_{1.0}Pb_{0.5}In_{0.5})Ba₄Tm₆Cu₈O₂₂+, (Sn_{1.0}Pb_{0.}5In_{0.5})Ba₄Tm₅Cu₇O₂₀+, (Sn_{1.0}Pb_{0.5}In_{0.5})Ba₄Tm₄Cu₆O ₁₈+, Sn₃Ba₄Ca₂Cu₇O_{y}, (Hg_{0.}8Tl_{0.2})Ba₂Ca₂Cu₃O_{8.33}, HgBa₂Ca₂Cu₃O₈, HgBa₂Ca₃Cu₄O₁₀+, HgBa₂(Ca₁₋ₓSrₓ)Cu₂O₆+, HgBa₂Cu)₄+, Tl₂Ba₂Ca₂Cu₃O₁₀, (Tl_{1.6}Hg_{0.4})Ba₂Ca₂Cu₃O₁₀+, TlBa₂Ca₂Cu₃O₉+, (TlSn)Ba₄TmCaCu₄O₁₄+, (Tl_{0.5}Pb_{0.5})Sr₂Ca₂Cu₃O₉, Tl₂Ba₂CaCu₂O₆, TlBa₂Ca₃Cu₄O₁₁, (SnTl_{0.5}Pb_{0.5})Ba₄Tm₃Cu₅O₁₆+, TlBa₂CaCu₂O₇+, Tl₂Ba₂CuO₆, TlSnBa₄Y₂Cu₄Oₓ, Sn₄Ba₄(Tm₂Ca)Cu₇Oₓ, Sn₂Ba₂(Tm_{0.5}Ca_{0.5})Cu₃O₈+, SnInBa₄Tm₃Cu₅Oₓ, Sn₃Ba₄Tm₃Cu₆Oₓ, Sn₃Ba₈Ca₄Cu₁₁Oₓ, SnBa₄Y₂Cu₅Oₓ, Sn₄Ba₄Tm₂YCu₇Oₓ, Sn₄Ba₄TmCaCu₄Oₓ, Sn₄Ba₄Tm₃Cu₇Oₓ, Sn₂Ba₂(Y_{0.5}Tm_{0.5})Cu₃O₈+, Sn₃Ba₄Y₂Cu₅Oₓ, SnInBa₄Tm₄Cu₆Oₓ, Sn₂Ba₂(Sr_{0.5}Y_{0.5})Cu₃O₈, Sn₄Ba₄Y₃Cu₇Oₓ, Bi_{1.6}Pb_{0.6}Sr₂Ca₂Sb_{0.1}Cu₃O_{y}, Bi₂Sr₂Ca₂Cu₃O₁₀, Bi₂Sr₂CaCu₂O₉, Bi₂Sr₂(Ca_{0.8}Y_{0.2})Cu₂O₈, Bi₂Sr₂CaCu₂O₈, CaSrCu₂O₄, YSrCa₂Cu₄O₈+, (Ba,Sr)CuO₂, BaSr₂CaCu₄O₈+, (La,Sr)CuO₂, Pb₃Sr₄Ca₃Cu₆Oₓ, Pb₃Sr₄Ca₂Cu₅O₁₅+, (Pb_{1.5}Sn_{1.5})Sr₄Ca₂Cu₅O₁₅+, Pb₂Sr₂(Ca, Y)Cu₃O₈, AuBa₂Ca₃Cu₄O₁₁, AuBa₂(Y, Ca)Cu₂O₇, AuBa₂Ca₂Cu₃O₉, YBa₃Cu₄Oₓ, YCaBa₃Cu₅O₁₁+, (Y_{0.5}Lu_{0.5})Ba₂Cu₃O₇, (Y_{0.5}Tm_{0.5})Ba₂Cu₃O₇, Y₃Ba₅Cu₈Oₓ, Y₃CaBa₄Cu₈O₁₈+, (Y_{0.5}Gd_{0.5})Ba₂Cu₃O₇, Y₂CaBa₄Cu₇O₁₆, Y₃Ba₄Cu₇O₁₆, Y₂Ba₅Cu₇Oₓ, NdBa₂Cu₃O₇, Y₂Ba₄Cu₇O₁₅, GdBa₂Cu₃O₇, YBa₂Cu₃O₇, TmBa₂Cu₃O₇, YbBa₂Cu₃O₇, YSr₂Cu₃O₇, GaSr₂(Ca_{0.5}Tm_{0.5})Cu₂O₇, Ga₂Sr₄Y₂CaCu₅Oₓ, Ga₂Sr₄Tm₂CaCu₅Oₓ, La₂Ba₂CaCu₅O₉+, (Sr,Ca)₅Cu₄O₁₀, GaSr₂(Ca, Y)Cu₂O₇, (In_{0.3}Pb_{0.7})Sr₂(Ca_{0.8}Y_{0.2})Cu₂Oₓ, (La,Sr,Ca)₃Cu₂O₆, La₂CaCu₂O₆+, (Eu,Ce)₂(Ba,Eu)₂Cu₃O₁₀+, (La_{1.85}, Sr_{0.15})CuO₄, SrNdCuO, (La,Ba)₂CuO₄, (Nd,Sr,Ce)₂CuO₄, Pb₂(Sr,La)₂Cu₂O₆, (La_{1.85}Ba.₁₅)CuO₄, RuSr₂(Gd,Eu,Sm)Cu₂O₈, Sr₂CuO₂Cl₂)
d) nickelates (RNiO₃, LaNiO₃)

Commercially available oxide systems:

AgGaSe₂, (CaLaₓ)MnO_{2.97}, (Gd₁₋ₓSrₓ)VO₃, (La,Sr)(Al,Ta)O₃ (LSAT), (La₁₋ₓSrₓ)CoO₃, (La₁₋ₓSrₓ)VO₃, (LaSrₓ)MnO₃, (Nd_{0.5}Sr_{0.5})MnO₃, AgGaS₂, Al₂O₃ (Saphire), BaB₂O₄ (BBO),BaF₂, BaTiO₃, BaVO₃, BaZrO₃, BeAl₂O₄, BeAl₆O₁₀, Bi₁₂GeO₂₀ (BGO), Bi₁₂SiO₂₀ (BSO), BiMnO₃, CaCO₃, CaCrO₃, CaF₂, CaFeO₃, CaHfO₃, CaMnO₃, CaNdAlO₄, CaRuO₃, CaTiO₃, CaVO₃, CaWO₄, CdS, CdSe, CdTe, CdWO₄, CeCrO₃, CeFeO₃, CeTiO₃, CeVO₃, Cu₂O, DyScO₃, EuNiO₃, Fe₂O₃, GaAs, GaP, Gd₃Ga₅O₁₂ (GGG), GdScO₃, Ge, InAs, InP, InSb, KBr, KCl, KD2PO4 (DKDP), KH₂PO₄ (KDP),KNbO₃, KTaO₃, KTiOPO₄ (KTP), La₂Be₂O₅, La₂Ti₂O₇, La₃Ga₅SiO₁₄, LaAlO₃, LaCoO₃, LaCrO₃, LaFeO₃, LaMnO₃, LaNiO₃, LaSrGaO₄, LaTiO₃, LaVO₃, LiAlO₃, LiB₃O₅ (LBO), LiF, LiGaO₂, LiAlO₂, LiIO₃, LiNbO₃, LiTaO₃, Mg₂SiO₄, MgAl₂O₄, MgF₂, MgO, NaCl, NaF, NdGaO₃, NdMnO₃, NdNiO₄, PbMoO₄, PrMnO₃, PrNiO₃, Si, SiC, SiO₂, SmNiO₃, SnO₂, SrCoO₃, SrCrO₃, SrFeO₃, SrLaAlO₄, SrLaGaO₄, SrMnO₃, SrO₂, SrRuO₃, SrTiO₃, SrVO₃, SrZrO₃, Tb₃Ga₅O₁₂ (TGG), TeO₂, TiO₂ (Anatase), TiO₂ (Rutile), Y₂0₃, Y₂SiO₅, Y₃Al₅O₁₂ (YAG), YAlO₃, YMnO₃, YNiO₃, YTiO₃, YVO₃, YVO₄, ZnO, ZnS, ZnSe, ZnTe)

List of common semiconductors
a) Group IV elemental semiconductors (C (Diamond), Si (Silicon), Ge (Germanium))
b) Group IV compound semiconductors (SiC, SiGe)
c) III-V semiconductors (AlSb, AlAs, AlN, AlP, BN, BP, BAs, B12As2, GaSb, GaAs, GaN, GaP, InSb, InAs, InN, InP, AlGaAs, InGaAs, InGaP, AlInAs, AlInSb, GaAsN, GaAsP, GaAsSb, AlGaN, AlGaP, In—GaN, InAsSb, InGaSb, AlGaInP, AlGaAsP, InGaAsP, InGaAsSb, InAsSbP, AlInAsP, AlGaAsN, InGaAsN, InAlAsN, GaAsSbN, GaInNAsSb, GaInAsSbP)
d) II-VI semiconductors (CdSe, CdS, CdTe)
e) II-VI, (ZnO, ZnSe, ZnS, ZnTe, CdZnTe, HgCdTe, HgZnTe, HgZnSe)
f) I-VII semiconductors (CuCl)
g) I-VI semiconductors (Cu2S)
h) IV-VI semiconductors (PbSe, PbS, PbTe, SnS, SnS2, SnTe, PbSnTe, Tl₂SnTe₅, Tl₂GeTe₅)
i) V-VI semiconductors (Bi₂Te₃)
j) II-V semiconductors (Cd₃P₂, Cd₃As₂, Cd₃Sb₂, Zn₃P₂, Zn₃As₂, Zn₃Sb₂)
k) Oxides semiconductors (TiO₂, Cu₂O, CuO, UO₂, UO₃, Bi₂O₃, SnO₂, BaTiO₃, SrTiO₃, LiNbO₃, La₂CuO₄)
l) Layered semiconductors (PbI₂, MoS₂, GaSe, SnS, Bi₂S₃)
m) Magnetic semiconductors (GaMnAs, InMnAs, CdMnTe, PbMnTe, La_{0.7}Ca_{0.3}MnO₃, FeO, NiO, EuO, EuS, CrBr₃)
n) Other semiconductors (Cu(In,Ga)Se₂, Cu₂ZnSnS₄, CuInSe₂, AgGaS₂, ZnSiP₂, As₂S₃, PtSi, BiI₃, HgI₂, T1Br, Se, Ag₂S, FeS₂)

The invention will be better understood in the following chapters, with examples and figures.

The invention is of course not limited to those examples.

The inventive idea relies on the fact that high energy radiation, like electrons and photons, can be used to create oxygen vacancies in some materials, in particular the anatase polymorph of TiO₂. Following the relationship Ti⁴⁺O₂²⁻→Ti⁴⁺₁₋ₓTi³⁺ₓ(O²⁻₂₋ₓ)+xe⁻. These oxygen vacancies act as electron donors for the electronic band structure of anatase and create a bulk metallic state at the center of its Brillouin zone. This state can be used as charge transport channel in anatase based applications. As such, we propose common radiation based lithography techniques (e.g. UV-, EUV-, e-beam-lithography) to directly write metallic patterns into otherwise stoichiometric, insulating anatase structures comprising thin films and bulk structures as well as nano-materials such as nano-particles and nano-rod structures. A simple example can be to grow a stoichiometric mono crystalline anatase thin film on top of a SrTiO₃ (001) substrate and then use (E)UV or e-beam lithography to write a grid of conductive channels into it. In a photovoltaic application e.g., the remaining stoichiometric parts could be then used as photoactive regions, whereas the non stoichiometric areas could be used to transport electrons away from the center of creation.

A) Evidence for the Metallic State

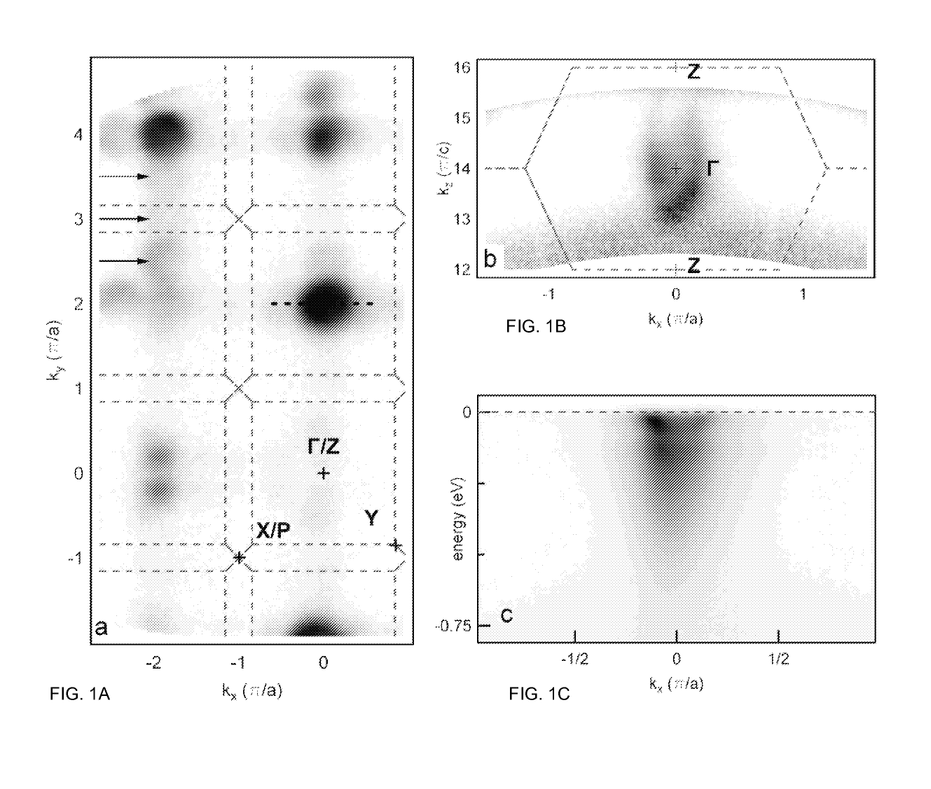

Irradiating stoichiometric anatase with (E)UV results in oxygen vacancy creation. Effectively, this corresponds to an electron doping of the system and the otherwise unoccupied lower part of the conduction band (CB) is populated. FIGS. 1A-1C show an overview of the effect observed in mono crystalline antatase thin films grown on Nb doped SrTiO3. The metallic state was probed by means of angle resolved photoemission spectroscopy (ARPES).

FIG. 1A shows a constant energy (CE) cut at the Fermi level taken at 85 eV photon energy. The blue dashed lines are projections of the three-dimensional Brillouin zone (BZ). Labels indicate the high symmetry points. The photon energy was adjusted to optimize signal of the electron pocket at kₓ=0 and k_{y}=2π/a=1.66 Å⁻¹ which corresponds to the Γ-point of the body centered tetragonal BZ. At normal emission, the metallic state is completely suppressed due to the d_{xy} symmetry of the CB orbitals. The black arrows in FIG. 1A indicate three replicas along the kₓ and k_{y} axis, that correspond to the band back folding on the 4×1 reconstruction of the anatase thin films. The kₓk_{z} CE contour of FIG. 1B for E=E_{F} and k_{y}=2π/a (dashed line in (a)) completely determines the shape, size and position in k-space of the electron pocket. It is an ellipsoid elongated in the c direction and centered at the Γ point, and confirms the bulk nature of the metallic state.

FIG. 1C shows an image cut along the dashed line in FIG. 1A. It reveals the metallic state at an intermediate doping level. Clearly, the electron pocket contains a very pronounced feature at the low binding energy side. It is dispersing electron like with its minimum at about 45 meV binding energy. In the further discussion, we will refer to this structure as the quasiparticle (QP) peak. Towards the high binding energy side, the QP is followed by a satellite and a broad tail, indicating the polaronic nature of the metallic state.

B) Control of the Metallic State/Reversibility

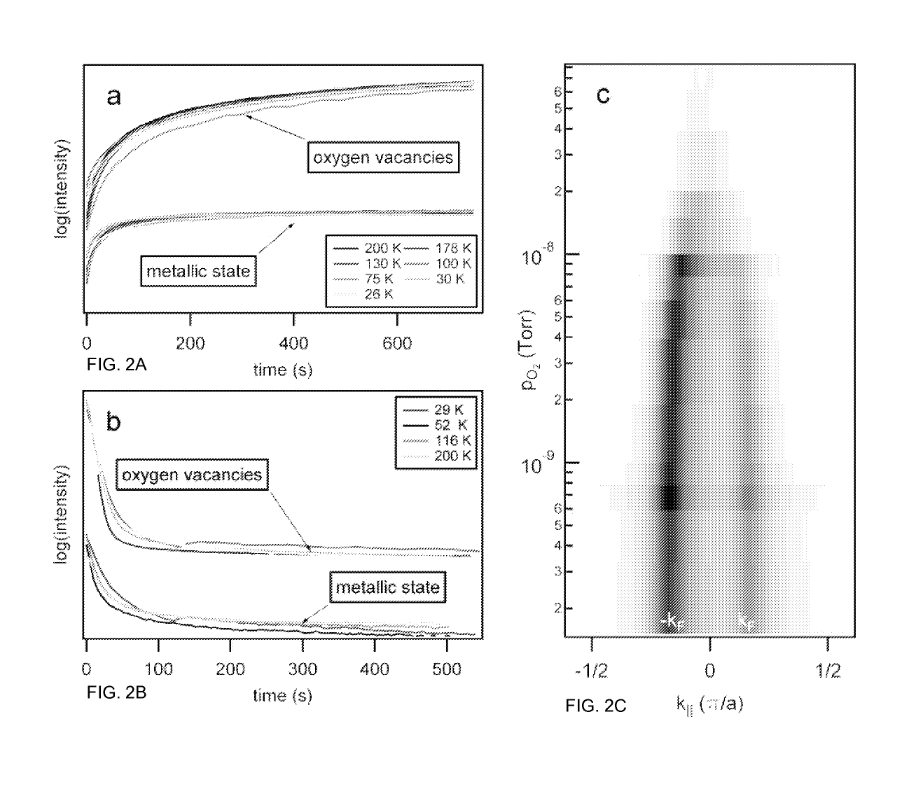

FIG. 2A shows a study of the oxygen vacancy formation while exposing the anatase thin film to 85 eV X-rays in ultra high vacuum<10⁻ Torr. The photoemission signal is integrated over E-k-windows of E=[−0.6; 0.1] eV times k=[−0.5; 0.5] Å⁻¹ for the metallic state and E=[−1.5;−0.6] eV times k=[−1;1] Å⁻¹ for the oxygen vacancy peak. At t=0, the anatase crystal is nearly stoichiometric and therefore almost insulating. We observe no signal at the Fermi level. However, with time, more and more oxygen vacancies are created by UV radiation. The additional electrons provided by oxygen vacancies populate the CB and the signal of the metallic state increases. After about 100 s, the signal of the metallic state saturates and no further population of the CB takes place, while oxygen vacancy formation continues. The negligible dependence of this effect on temperature shows that T=200 K is well below the threshold that drives oxygen vacancy diffusion processes in anatase. This is consistent with recent experiments on anatase (101) surface by Scheiber et. al.¹²

FIG. 2B shows a study of the reverse process. Here, the time dependence of a fully saturated metallic state is monitored while some fixed pressure of oxygen is applied to the sample. The oxygen is replenishing the O-vacancy sites, which therefore competes with the effect of irradiation. The major drop of metallic state and oxygen vacancy state occurs during the first 100 s, indicating surface and subsurface re-oxidation. The ongoing lowering of signal after 100 s may result from re-oxidation of deeper TiO₂ layers. Again, the effect is not temperature dependent up to 200 K.

The competition between O replenishing and O vacancy formation can be used to continuously control the electron doping of the system as shown in FIG. 2C. Here, a cut of the Fermi surface along the kₓ direction is shown as a function of oxygen pressure and at constant photon flux. By dosing the amount of oxygen during this “lithographic process” the charge carrier concentration can be continuously tuned from 0 to about 10²⁰ cm⁻³.

For very low carrier concentrations 10¹⁷ cm⁻³ population of the CB takes place from a donor level about 10 meV below the CB. Therefore, the CB depopulates at temperatures below 100 K. At higher doping 10¹⁸ cm⁻³, donor states eventually merge and hybridize with the CB, forming mobile large polaron QPs of about 2 nm radius. These remain mobile throughout all temperature regimes. For even higher dopings 5×10¹⁹ cm₋³, polarons finally dissolve in a Fermi liquid.

C) Stability of the Metallic State

Two major problems endanger the stability of metallic anatase regions created by oxygen defects: first, applications in ambient atmosphere present the risk of refilling from the oxygen in air. This effect can in principle be avoided by capping techniques. In some applications like photo catalysis, a stoichiometric surface region might even be of interest.

A second problem might result from bulk diffusion of oxygen vacancies, which would confine the lifetime of a device to the typical timescale of the defect diffusion process.

Our observations indicate that non-stoichiometrically grown single crystals remain stable over long time in ambient pressure and temperature. A thorough re-oxidation requires annealing these crystals for several days in air at temperatures as high as 600° C., which indicates defect stability. Very few studies treated this problem experimentally at the microscale so far. A recent study on anatase (101) surfaces found oxygen vacancies migrating towards the subsurface for temperatures higher than 200 K, corresponding to a sub-surface migration activation energy of about 0.6-1.2 eV. Hence, vacancies are more stable in the bulk than at the surface^{12,13}.

D) Direct Lithography on Anatase

In principle, all types of radiation with energies higher than the oxygen defect formation energy in anatase could be used to write a metallic pattern. However, for fabrication purposes, some techniques will be more suitable than others.

1) UV/EUV/X-Ray Lithography

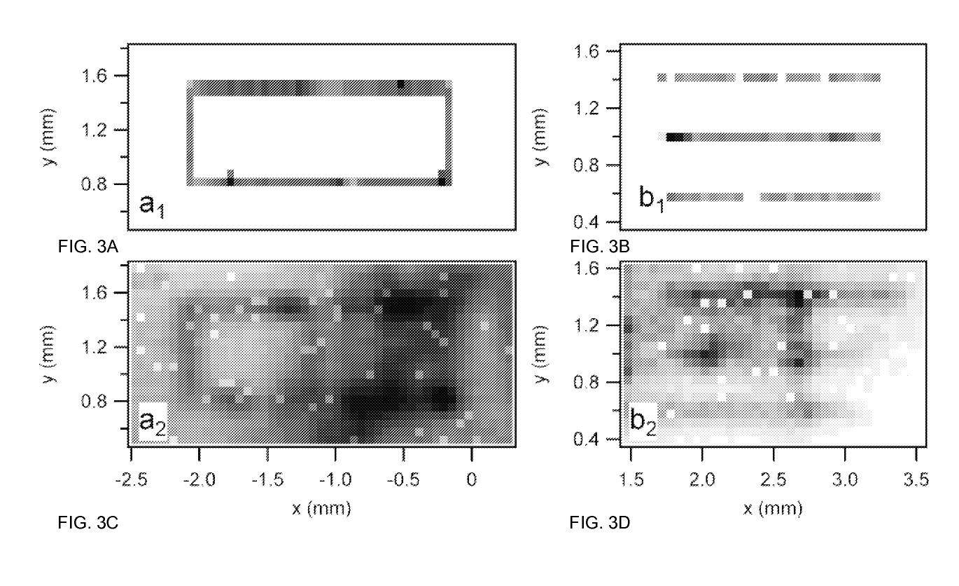

EUV lithography is currently developed to become the new standard lithographic technique in industry. Like the related and well established UV based technique, it is time efficient since large areas can be patterned in parallel. However, the much shorter wavelength used (13.5 nm) allows for much higher spatial resolution. Since its corresponding photon energy is securely overcoming the oxygen vacancy creation threshold in anatase, the technique can be directly used to write metallic patterns on large areas of anatase, e.g. an anatase thin film on a standard size SrTiO₃ wafer. A demonstration of the patterning effect of anatase is shown in FIGS. 3A-3D. In the first step, a stoichiometric grown anatase thin film is illuminated according to the pattern shown in FIG. 3A and FIG. 3B. Afterwards, the surface is imaged by scanning the region of interest and measuring the photoemission intensity at the Fermi level. Since this probing step involves x-ray illumination to generate the photoelectron signal, the background intensity of the non-patterned region is always nonzero. In FIG. 3D, a vertical streak can be seen which results from RHEED measurements during film deposition. This is the indirect proof that e-beam lithography is also a suitable technique for direct anatase patterning.

2) E-Beam Lithography

Electron beam lithography is still one of the most widespread and most efficient lithographic tools to push the resolution limit of semiconductor devices. With its resolution determined in principle by the de Broglie wavelength of the electrons, nano-devices as narrow as 5 nm have been reported. From the time efficiency standpoint, e-beam lithography cannot compete with mask-based techniques since it is a sequential writing rather than parallel illumination technique. Anyway, e-beam lithography has been used commercially in low volume device fabrication.

3) Focused Ion Beam/Laser Writing/Interference Lithography

Less common techniques like focused Ion beam, laser writing and interference lithography in principle are also suitable for writing a metallic state into anatase.

E) Industrial Implementation

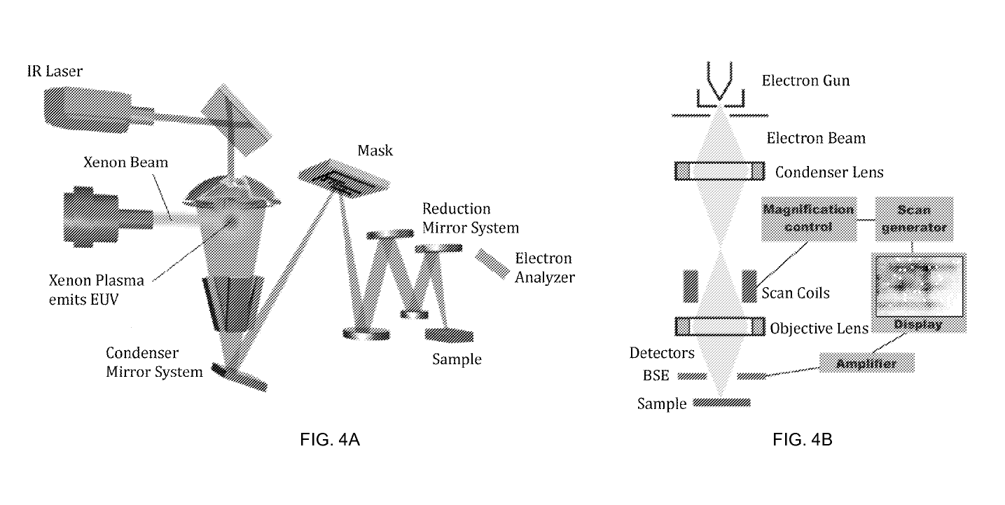

FIG. 4A shows an example how to implement the invention to an industrial large scale EUV lithographic fabrication process. In this EUV lithography setup, the ultraviolet light is created in a Xenon Plasma source, focused by a condenser minor and projected onto a lithography mask. The pattern of this mask in the following is mapped on top of the sample, e.g. an anatase thin film. Controlled electronic feedback can be implemented by different in situ mechanisms e.g.:
a) An in situ transport probe can be used to measure the charge carrier density in the illuminated areas.
b) The photoelectron emission spectrum, stimulated by the EUV light can be analyzed to determine the charge carrier density.
c) The fluorescence spectrum stimulated by the EUV light can be used to in situ determine the stoichiometry of the illuminated area and hence to determine the carrier density.
d) The low frequency reflectivity of the sample can be measured spatially to determine the charge carrier concentration.

Sample structuring and characterization as well as further processing steps take place in vacuum. Since the penetration depth of 13.5 nm x-rays is of the order of 50 nm, this fabrication process should be ideal in nano-structures of the order of hundreds of nanometers (e.g. memristor fabrication).

FIG. 4B shows a typical scheme of a scanning electron lithograph. An electron beam is bundled by complex electromagnetic lenses and focused onto the sample, e.g. an anatase thin film. Controlled variation of the lens potential allows moving the electron beam along a desired pattern. Controlled electronic feedback can be implemented by different in situ mechanisms e.g.:
a) An in situ transport probe can be used to measure the charge carrier density in the illuminated areas.
b) The Auger electron emission spectrum, stimulated by the impinging electrons can be analyzed to determine the charge carrier density.
c) The signal of backscattered electrons (BSE) can be used to in situ determine the stoichiometry of the illuminated area and hence to determine the carrier density.
d) Cathodoluminescence can be used to in situ determine the stoichiometry of the illuminated area and hence to determine the carrier density.
e) The low frequency reflectivity of the sample can be measured spatially to determine the charge carrier concentration.

Sample structuring and characterization as well as further processing steps take place in vacuum. Since the penetration depth of the electrons can be varied as a function of the electron energy (e.g. 5 μm for 30 kV electrons), this fabrication process should be ideal in applications where metallic anatase is used as a charge transport electrode (e.g. solar panels . . . ).

Other Applications

In the following, proposals for applications will be related explicitly to TiO₂ anatase. However, similar applications based on different material systems (see section III) eligible for the invention as presented in this paper may be applied.

TiO₂ is a semiconductor with a number of properties pertinent to photocatalysis such as transparency to visible light, high refractive index and low absorption coefficient and has been of particular interest due to its low cost, low toxicity, chemical stability (both to light and the environment) and high photo-activity. A wide range of applications including ultraviolet filters for optics and packing materials, environmental re-mediation, papermaking, ceramics, solar cells, electrochromic displays, anodes for ion batteries, self-cleaning coatings and paints, anti-microbial coatings and surfaces degrading organic contaminants, optical interference coatings and humidity as well as gas sensors have been realized.

The invention presented in this document can be used in an almost infinite number of devices, where the charge carrier density and behavior of anatase (or similar as explained in section III)) needs to be controlled. Most important, it can be used wherever transparent insulating anatase needs to be contacted or interfaced with a semiconducting or metallic electrode, or a spatial modulation of the charge carrier density defines its functionalities. For example, the direct lithographic imprint of metallic regions into anatase can be used to spatially modulate the dielectric properties of the material and hence find application in optical and field effect devices. In the following sections, some of many possible applications are listed in more detail:

A) Solar Cells

TiO₂ anatase based photovoltaic applications like the famous “Gratzel cell” base on either of two working principles^{2,14}: either, an absorbed photon creates an electron hole pair directly in the anatase semiconductor itself, or the excitation takes place in a dye attached to and then transferred to anatase. In any case, the electron hole pairs have to be separated and transported to metallic electrodes before charge recombination at impurities and interfaces can take place. Our method enables a nano-scale spatial variation from semiconducting to metallic anatase, guaranteeing smooth band alignment without creating a crystal interface. This can help avoiding charge recombination centers, and allows for charge collection close to the creation center.

B) Photoelectrochemical Devices

Chemical fuels are an excellent way to store energy. In contrast to photovoltaics, photo-catalysis aims for direct energy transfer of a photon to a chemical bond, rather than to a current. The most prominent example hereof is photosynthesis in plants. In a technical application, photo-catalytic water splitting into oxygen and hydrogen is considered feasible on a large scale basis¹⁵. The red ox potentials of water are well aligned with the electronic bands of anatase. Hence, electron-hole pair creation can stimulate a catalytic reaction to split water molecules on the surface of anatase, given that the charge reaches the surface before recombination^{3.16}. Besides, a large scale process requires to separate H₂ and O₂ production for security reasons. A conductive channel directly imprinted in anatase could provide a way to separate electrons from holes and thus spatially separate hydrogen from oxygen production while diminishing electron hole pair recombination.

C) Optical Devices

The invention allows to spatially pattern the electronic structure of anatase defining locally the dielectric nature of the material. This allows for a wide range of optical applications like waveguides, gratings, photonic crystals and similar structures¹⁷⁻²⁰.

D) Gas Sensors

In gas sensing applications, TiO₂ has been well established due to its stability against corrosion, and its favorable catalytic properties. In surface layer controlled gas sensors, the charge carrier concentration of the device is varied as a result of surface reactions^{21,22}. This variation can then be read out electronically. Developing more efficient sensors requires increasing sensitivity, in principle to the limit where single surface reaction events can be detected. Major constraint here is the loss of charge between the sensing point and the charge counting electronics. To reduce charge decay channels, metallic anatase can be used to transport charge from the sensing point to an electrode. Thus, significant progress in raising sensitivity can be possible.

E) Electrochromic Displays

In 1982, TiO₂ was first proposed as material for electrochromic displays and ever since the idea has been pushed forward^{23,24}. When a burst of charge is applied to this kind of device, it reversibly changes its color based on certain red ox reactions. The efficiency of an electrochromic display is based on the interfacial electron transfer between the nano-crystalline electrode and the anchored electrochromophore during the red ox reaction. To transfer charge from and to the device, a fast reliable transport channel is needed that could be created by the lithography method proposed in this invention.

F) Capacitors, Varistors, Resistors, Inductors, Memristors, Magnetic Spin Valves, Mosfets and Other Electronic/Spintronic Devices

With a relatively high dielectric constant of K=80, TiO₂ finds possible applications in several passive and active electronic components where a high field effect is of interest. A typical example is a metal oxide semiconductor field effect transistor (MOSFET) where an electric field across a capacitor controls the conductivity of a current channel. Fast and efficient devices require pinhole free oxide layers smoothly connected to a gate electrode that could be realized by lithographically patterned, oxygen vacant TiO₂ .A passive device that has drawn lots of interest, especially to the industry, is the memristor, where an electric field is used to move oxygen vacancies to open and close a conductive current channel while modifying the internal state of the device^{1,25}. This internal change allows the device to keep a memory, i.e, the new switching state of the memristor depends on its history. In state of the art devices, the active switching channel containing oxygen vacancies is created by diffusion processes from and to adjacent electrodes. A direct lithographic method as proposed in this invention allows for a local control of the stoichiometry of anatase and can therefore guarantee reproducible switching characteristics of memristor devices implemented on a large scale.

### REFERENCES

1. D. B. Strukov, G. S. Snider, D. R. Stewart, and R. S. Williams, Nature 459 (2009).
2. B. O'Regan and M. Grätzel, Nature 353, 737 (1991).
3. R. Asahi, T. Morikawa, T. Ohwaki, K. Aoki, and Y. Taga, Science 293, 269 (2001).
4. Y. Ohko, T. Tatsuma, T. Fujii, K. Naoi, C. Niwa, Y. Kubota, and A. Fujishima, Nature Mater. 2, 29 (2003).
5. H. Toyosaki, T. Fukumura, Y. Yamada, K. Nakajima, T. Chikyow, T. Hasegawa, H. Koinuma, and M. Kawasaki, Nature Mater. 3, 221 (2004).
6. Y. Furubayashi, T. Hitosugi, Y. Yamamoto, K. Inaba, G. Kinoda, Y. Hirose, T. Shimada, and T. Hasegawa, Appl. Phys. Lett. 86, 252101 (2005).
7. N. Tetreault, E. Horvath, T. Moehl, J. Brillet, R. Smajda, S. Bungener, N. Cai, P. Wang, S. M. Zakeeruddin, L. Forro, et al., Acs Nano 4, 7644 (2010).
8. Y. Yamada, K. Ueno, T. Fukumura, H. T. Yuan, H. Shimotani, Y. Iwasa, L. Gu, S. Tsukimoto, Y. Ikuhara, and M. Kawasaki, Science 332, 1065 (2011).
9. T. Umebayashi, T. Yamaki, H. Itoh, and K. Asai, Appl. Phys. Lett. 81, 454 (2002).
10. C. Burda, Y. B. Lou, X. B. Chen, A. C. S. Samia, J. Stout, and J. L. Gole, Nano Lett. 3, 1049 (2003).
11. W. Zhu, X. Qiu, V. Iancu, X.-Q. Chen, H. Pan, W. Wang, N. M. Dimitrijevic, T. Rajh, I. Meyer, Harry M., M. P. Paranthaman, et al., Phys. Rev. Lett. 103, 226401 (2009).
12. P. Scheiber, M. Fidler, O. Dulub, M. Schmid, U. Diebold,W. Hou, U. Aschauer, and A. Selloni, Phys. Rev. Lett. 109, 136103 (2012).
13. L. Forro, O. Chauvet, D. Emin, L. Zuppiroli, H. Berger, and F. Levy, J. Appl. Phys. 75, 633 (1994).
14. C. J. Barbe, F. Arendse, P. Comte, M. Jirousek, F. Lenzmann, V. Shklover, and M. Gratzel, J. Am. Cer. Soc. 80, 3157 (1997).
15. B. D. James, G. N. Baum, J. Perez, and K. N. Baum, Tech. Rep., Directed Technologies, One Virginia Square 3601 Wilson Boulevard, Suite 650 Arlington, Va. 22201 (703) 243-3383 (2009).
16. A. Fujishima, T. N. Rao, and D. A. Tryk, J. Photochem. Photobiol. C: Photochem. Rev. 1, 1 (2000).
17. M. Yoshida and P. N. Prasad, Chem. Mat. 8, 235 (1996).
18. M. Yoshida and P. N. Prasad, Appl. Opt. 35, 1500 (1996)
19. W. Que, Y. Zhou, Y. L. Lam, Y. C. Chan, and C. H. Kam, Appl. Phys. A Mater. Sci. Process. 73, 171 (2001).
20. W. X. Que and C. H. Kam, Opt. Eng. 41, 1733 (2002).
21. S. Arakawa, K. Mogi, K. Kikuta, T. Yogo, and S. Hirano, J. Am. Cer. Soc. 82, 225 (1999).
22. D. P. Smetaniuk, M. T. Taschuk, and M. J. Brett, IEEE Sens. J. 11, 1713 (2011).
23. T. Ohzuku and T. Hirai, Electrochim. Acta 27, 1263 (1982).
24. H. K. Jheong, Y. J. Kim, J. H. Pan, T.-Y. Won, and W. I. Lee, J. Electroceram. 17, 929 (2006).
25. S. Williams, IEEE Spec. 45, 24 (2008).

What is claimed is:

1. A method of lithographic patterning a material, the material being an insulating or semiconducting solid state material in a crystalline form, comprising:
exposing the material to an amount of radiation which is sufficient to change an insulating state or a semiconducting state of the material to a conducting state.

2. The method of claim 1, wherein the material comprises an oxide.

3. The method of claim 2, wherein the oxide comprises anatase polymorph of TiO₂.

4. The method of claim 3, wherein that radiation has an energy which is higher than the oxygen defect formation energy in anatase.

5. The method of claim 4, wherein the radiation has an energy between 80 eV and 100 eV.

6. The method of claim 1, wherein the material comprises a sulfide, a selenide, a telluride, a nitride, a phosphide, an arsenide, a fluoride, a chloride, a bromide, a carbide, or an iodide of a transition metal, a rare earth metal, an alkali metal, an alkaline earth metals, or one of the elements C, Al, Si, Ga, Ge, As, In, Sn, Sb, Te, Tl, Pb, Bi, Po.

7. The method of claim 1, wherein the material comprises a ternary or a higher order compound.

8. The method of claim 1, wherein the material comprises an alloy of like compounds with each other or a mixed compound with two, three, or more different metal atoms combined with some number of electronegative elements.

9. The method of claim 1, wherein the radiation is selected from a group consisting of electrons, extreme ultraviolet (EUV), ions, and laser light.

10. The method of claim 1, further comprising:
exposing the material to a gas while exposing the material to the amount of radiation.

11. The method of claim 10, wherein the gas comprises oxygen.
